(19) United States
(12) Patent Application Publication
(10) Pub. No.: US 2005/0136666 A1
(43) Pub. Date: Jun. 23, 2005

(54) Method and apparatus for etching an organic layer

(75) Inventors: Vaidyanathan Balasubramaniam, Richardson, TX (US); Koichiro Inazawa, Peabody, MA (US); Siddhartha Panda, Beacon, NY (US); Rich Wise, New Windsor, NY (US); Arpan P. Mahorowala, Bronxville, NY (US)

Correspondence Address: PILLSBURY WINTHROP SHAW PITTMAN, LLP, P.O. BOX 10500, MCLEAN, VA, 22102, US

(73) Assignees: Tokyo Electron Limited, Tokyo (JP); International Business Machines Corporation, Armonk, NY (US)

(21) Appl. No.: 10/787,898

(22) Filed: Feb. 27, 2004

Related U.S. Application Data
(63) Continuation-in-part of application No. 10/743,256, filed on Dec. 23, 2003, now abandoned.

(51) Int. Cl. H01L 21/302; H01L 21/461

(52) U.S. Cl. 438/689

(57) ABSTRACT

A method and system for etching an organic layer on a substrate in a plasma processing system comprising: introducing a process gas comprising NₓO_{y}, wherein x, y represent integers greater than or equal to unity. Additionally, the process chemistry can further comprise the addition of an inert gas, such as a Noble gas (i.e., He, Ne, Ar, Kr, Xe, Rn). The present invention further presents a method for forming a bilayer mask for etching a thin film on a substrate, wherein the method comprises: forming the thin film on the substrate; forming an organic layer on the thin film; forming a photoresist pattern on the organic layer; and transferring the photoresist pattern to the organic layer with an etch process using a process gas comprising NₓO_{y}, wherein x, y represent integers greater than or equal to unity.

This application is a continuation-in-part of application Ser. No. 10/743,256, filed Dec. 23, 2003, the entire contents of which are incorporated herein by reference.

### FIELD OF THE INVENTION

The present invention relates to a method and apparatus for plasma processing a substrate, and more particularly to a method and apparatus for etching an organic layer.

### BACKGROUND OF THE INVENTION

During semiconductor processing, a (dry) plasma etch process can be utilized to remove or etch material along fine lines or within vias or contacts patterned on a silicon substrate. The plasma etch process generally involves positioning a semiconductor substrate with an overlying patterned, protective layer, for example a photoresist layer, in a processing chamber. Once the substrate is positioned within the chamber, an ionizable, dissociative gas mixture is introduced within the chamber at a pre-specified flow rate, while a vacuum pump is throttled to achieve an ambient process pressure. Thereafter, a plasma is formed when a fraction of the gas species present are ionized by electrons heated via the transfer of radio frequency (RF) power either inductively or capacitively, or microwave power using, for example, electron cyclotron resonance (ECR). Moreover, the heated electrons serve to dissociate some species of the ambient gas species and create reactant specie(s) suitable for the exposed surface etch chemistry. Once the plasma is formed, selected surfaces of the substrate are etched by the plasma. The process is adjusted to achieve appropriate conditions, including an appropriate concentration of desirable reactant and ion populations to etch various features (e.g., trenches, vias, contacts, etc.) in the selected regions of the substrate. Such substrate materials where etching is required include silicon dioxide (SiO₂), low-k dielectric materials, poly-silicon, and silicon nitride.

### SUMMARY OF THE INVENTION

The present invention relates to a method and apparatus for etching an organic layer in a plasma process. A process gas comprises NₓO_{y}, wherein x, y are integers greater than or equal to unity. A plasma is formed from the process gas in the plasma processing system. The organic layer is exposed to the plasma.

Additionally, a method and apparatus are described for forming a bilayer mask for etching a thin film on a substrate. The thin film is formed on the substrate. An organic layer is formed on the thin film. A photoresist pattern is formed on the organic layer. The photoresist pattern is transferred to the organic layer by etching the organic layer using a process gas comprising NₓO_{y}, wherein x, y are integers greater than or equal to unity.

### BRIEF DESCRIPTION OF THE DRAWINGS

In the accompanying drawings:

FIGS. 1A, 1B, and 1C show a schematic representation of a typical procedure for pattern etching a thin film;

FIG. 2 shows a simplified schematic diagram of a plasma processing system according to an embodiment of the present invention;

FIG. 3 shows a schematic diagram of a plasma processing system according to another embodiment of the present invention;

FIG. 4 shows a schematic diagram of a plasma processing system according to another embodiment of the present invention;

FIG. 5 shows a schematic diagram of a plasma processing system according to another embodiment of the present invention;

FIG. 6 shows a schematic diagram of a plasma processing system according to another embodiment of the present invention;

FIG. 7 presents a method of etching an organic layer on a substrate in a plasma processing system according to an embodiment of the present invention; and

FIG. 8 presents a method of forming a bilayer mask for etching a thin film on a substrate according to another embodiment of the present invention.

### DETAILED DESCRIPTION OF SEVERAL EMBODIMENTS

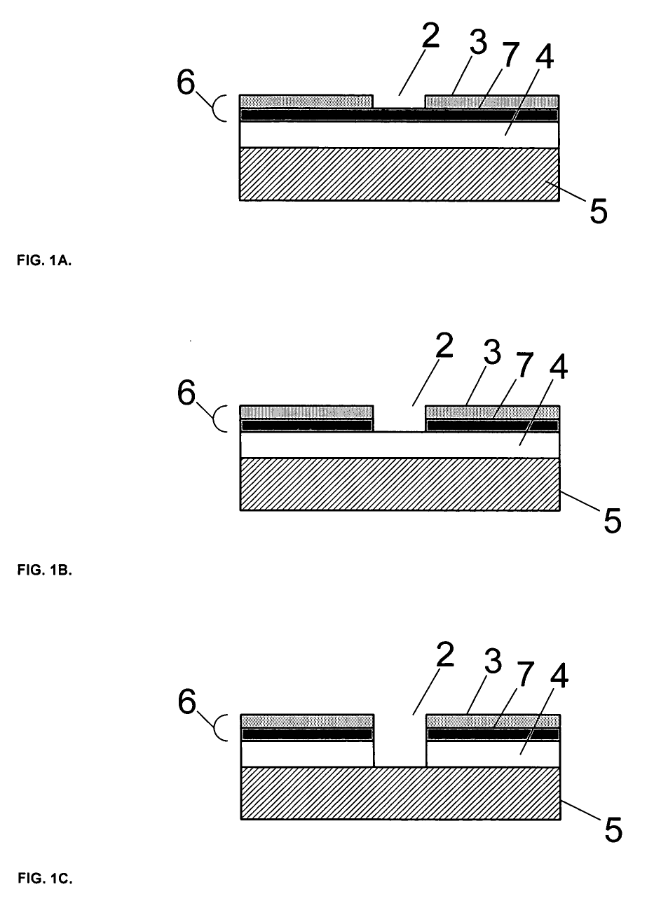

In material processing methodologies, pattern etching comprises the application of a thin layer of light-sensitive material, such as photoresist, to an upper surface of a substrate, that is subsequently patterned in order to provide a mask for transferring this pattern to the underlying thin film during etching. The patterning of the light-sensitive material generally involves exposure by a radiation source through a reticle (and associated optics) of the light-sensitive material using, for example, a micro-lithography system, followed by the removal of the irradiated regions of the light-sensitive material (as in the case of positive photoresist), or non-irradiated regions (as in the case of negative resist) using a developing solvent. Multi-layer masks can be implemented for etching features in a thin film. For example, as shown in FIGS. 1A-C, a bilayer mask 6 comprising light-sensitive layer 3 with pattern 2 formed using conventional lithographic techniques and an organic layer 7, such as an organic anti-reflective coating (ARC), an organic mask layer, combination thereof or the like, can be utilized as a mask for etching the thin film 4, wherein the mask pattern 2 in the light-sensitive layer 3 is transferred to the organic layer 7 using a separate etch step preceding the main etch step for the thin film 4.

In one embodiment, a process gas comprising a NₓO_{y} is utilized, wherein x, y represent integers greater than or equal to unity. The process gas comprising NₓO_{y} can include at least one of NO, NO₂, and N₂O. Alternately, the process gas can further comprise an inert gas, such as a Noble gas (i.e., He, Ne, Ar, Kr, Xe, Rn).

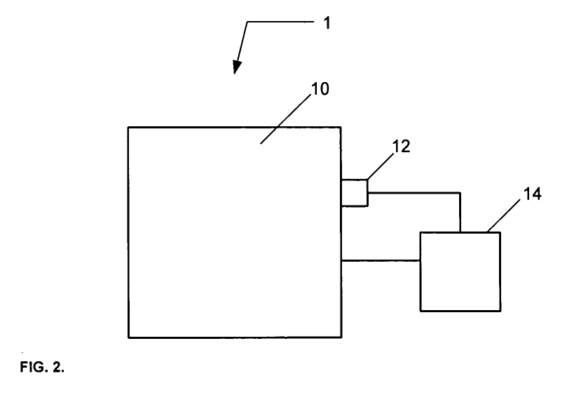

According to one embodiment, a plasma processing system 1 is depicted in FIG. 2 comprising a plasma processing chamber 10, a diagnostic system 12 coupled to the plasma processing chamber 10, and a controller 14 coupled to the diagnostic system 12 and the plasma processing chamber 10. The controller 14 is configured to execute a process recipe comprising at least one of the above-identified chemistries (i.e. NₓO_{y}, etc.) to etch an organic layer. Additionally, controller 14 is configured to receive at least one endpoint signal from the diagnostic system 12 and to post-process the at least one endpoint signal in order to accurately determine an endpoint for the process. In the illustrated embodiment, plasma processing system 1, depicted in FIG. 2, utilizes a plasma for material processing. Plasma processing system 1 can comprise an etch chamber.

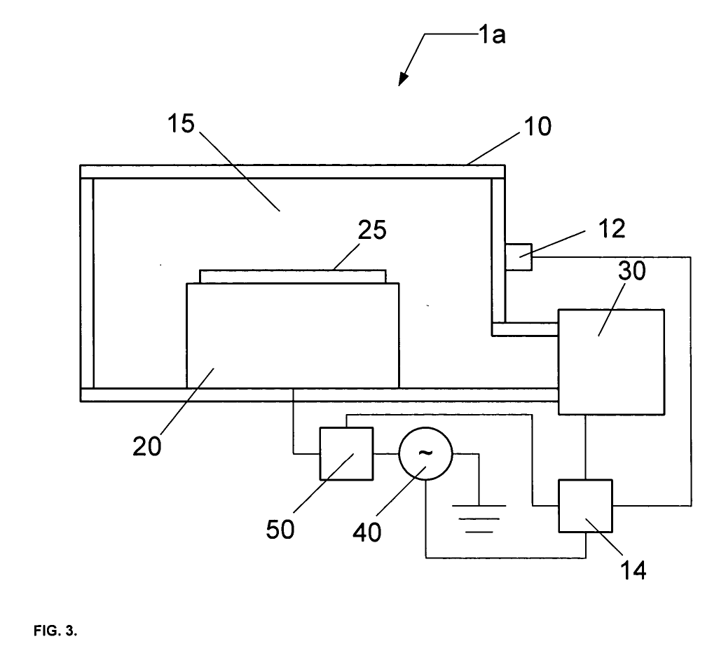

According to the embodiment depicted in FIG. 3, plasma processing system 1a can comprise plasma processing chamber 10, substrate holder 20, upon which a substrate 25 to be processed is affixed, and vacuum pumping system 30. Substrate 25 can be a semiconductor substrate, a wafer or a liquid crystal display. Plasma processing chamber 10 can be configured to facilitate the generation of plasma in processing region 15 adjacent a surface of substrate 25. An ionizable gas or mixture of gases is introduced via a gas injection system (not shown) and the process pressure is adjusted. For example, a control mechanism (not shown) can be used to throttle the vacuum pumping system 30. Plasma can be utilized to create materials specific to a pre-determined materials process, and/or to aid the removal of material from the exposed surfaces of substrate 25. The plasma processing system 1a can be configured to process substrates of any desired size, such as 200 mm substrates, 300 mm substrates, or larger.

Substrate 25 can be affixed to the substrate holder 20 via an electrostatic clamping system. Furthermore, substrate holder 20 can further include a cooling system including a re-circulating coolant flow that receives heat from substrate holder 20 and transfers heat to a heat exchanger system (not shown), or when heating, transfers heat from the heat exchanger system. Moreover, gas can be delivered to the back-side of substrate 25 via a backside gas system to improve the gas-gap thermal conductance between substrate 25 and substrate holder 20. Such a system can be utilized when temperature control of the substrate is required at elevated or reduced temperatures. For example, the backside gas system can comprise a two-zone gas distribution system, wherein the helium gas gap pressure can be independently varied between the center and the edge of substrate 25. In other embodiments, heating/cooling elements, such as resistive heating elements, or thermoelectric heaters/coolers can be included in the substrate holder 20, as well as the chamber wall of the plasma processing chamber 10 and any other component within the plasma processing system 1a.

In the embodiment shown in FIG. 3, substrate holder 20 can comprise an electrode through which RF power is coupled to the processing plasma in process space 15. For example, substrate holder 20 can be electrically biased at a RF voltage via the transmission of RF power from a RF generator 40 through an impedance match network 50 to substrate holder 20. The RF bias can serve to heat electrons to form and maintain plasma. In this configuration, the system can operate as a reactive ion etch (RIE) reactor, wherein the chamber and an upper gas injection electrode serve as ground surfaces. A typical frequency for the RF bias can range from about 0.1 MHz to about 100 MHz. RF systems for plasma processing are well known to those skilled in the art.

Alternately, RF power is applied to the substrate holder electrode at multiple frequencies. Furthermore, impedance match network 50 serves to improve the transfer of RF power to plasma in plasma processing chamber 10 by reducing the reflected power. Match network topologies (e.g. L-type, π-type, T-type, etc.) and automatic control methods are well known to those skilled in the art.

Vacuum pump system 30 can include a turbo-molecular vacuum pump (TMP) capable of a pumping speed up to about 5000 liters per second (and greater) and a gate valve for throttling the chamber pressure. In conventional plasma processing devices utilized for dry plasma etch, a 1000 to 3000 liter per second TMP is generally employed. TMPs are useful for low pressure processing, typically less than about 50 mTorr. For high pressure processing (i.e., greater than about 100 mTorr), a mechanical booster pump and dry roughing pump can be used. Furthermore, a device for monitoring chamber pressure (not shown) can be coupled to the plasma processing chamber 10. The pressure measuring device can be, for example, a Type 628B Baratron absolute capacitance manometer commercially available from MKS Instruments, Inc. (Andover, Mass.).

Controller 14 comprises a microprocessor, memory, and a digital I/O port capable of generating control voltages sufficient to communicate and activate inputs to plasma processing system 1a as well as monitor outputs from plasma processing system 1a. Moreover, controller 14 can be coupled to and can exchange information with RF generator 40, impedance match network 50, the gas injection system (not shown), vacuum pump system 30, as well as the backside gas delivery system (not shown), the substrate/substrate holder temperature measurement system (not shown), and/or the electrostatic clamping system (not shown). For example, a program stored in the memory can be utilized to activate the inputs to the aforementioned components of plasma processing system 1a according to a process recipe in order to perform the method of etching an organic layer. One example of controller 14 is a DELL PRECISION WORKSTATION 610™, available from Dell Corporation, Austin, Tex.

The diagnostic system 12 can include an optical diagnostic subsystem (not shown). The optical diagnostic subsystem can comprise a detector such as a (silicon) photodiode or a photomultiplier tube (PMT) for measuring the light intensity emitted from the plasma. The diagnostic system 12 can further include an optical filter such as a narrow-band interference filter. In an alternate embodiment, the diagnostic system 12 can include at least one of a line CCD (charge coupled device), a CID (charge injection device) array, and a light dispersing device such as a grating or a prism. Additionally, diagnostic system 12 can include a monochromator (e.g., grating/detector system) for measuring light at a given wavelength, or a spectrometer (e.g., with a rotating grating) for measuring the light spectrum such as, for example, the device described in U.S. Pat. No. 5,888,337.

The diagnostic system 12 can include a high resolution Optical Emission Spectroscopy (OES) sensor such as from Peak Sensor Systems, or Verity Instruments, Inc. Such an OES sensor has a broad spectrum that spans the ultraviolet (UV), visible (VIS), and near infrared (NIR) light spectrums. The resolution is approximately 1.4 Angstroms, that is, the sensor is capable of collecting 5550 wavelengths from 240 to 1000 nm. The OES sensor can be equipped with high sensitivity miniature fiber optic UV-VIS-NIR spectrometers which are, in turn, integrated with 2048 pixel linear CCD arrays.

The spectrometers receive light transmitted through single or bundled optical fibers, where the light output from the optical fibers is dispersed across the line CCD array using a fixed grating. Similar to the configuration described above, light emitting through an optical vacuum window is focused onto the input end of the optical fibers via a convex spherical lens. Three spectrometers, each specifically tuned for a given spectral range (UV, VIS and NIR), can form a sensor for a process chamber. Each spectrometer can include an independent A/D converter. And lastly, depending upon the sensor utilization, a full emission spectrum can be recorded every 0.1 to 1.0 seconds.

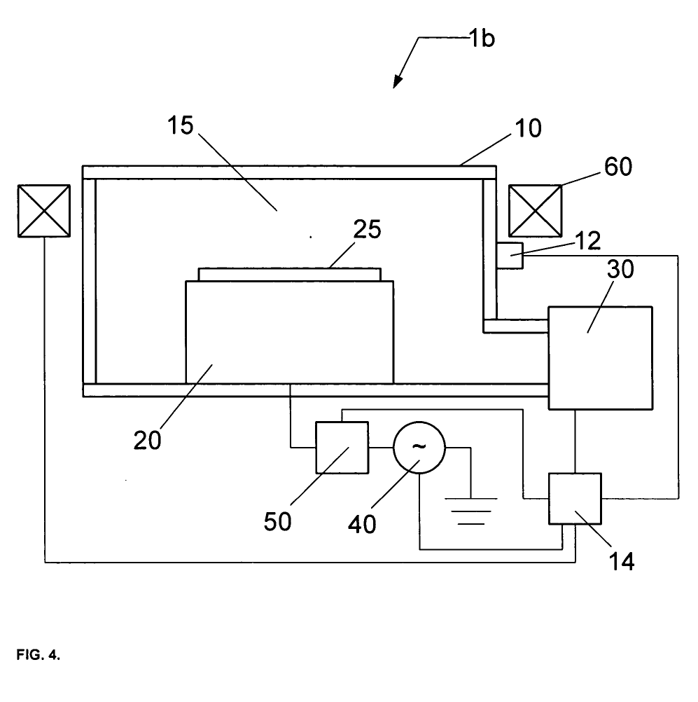

In the embodiment shown in FIG. 4, the plasma processing system 1b can be similar to the embodiment of FIG. 2 or 3 and further comprise either a stationary, or mechanically or electrically rotating magnetic field system 60, in order to potentially increase plasma density and/or improve plasma processing uniformity, in addition to those components described with reference to FIG. 2 and FIG. 3. Moreover, controller 14 can be coupled to magnetic field system 60 in order to regulate the speed of rotation and field strength. The design and implementation of a rotating magnetic field is well known to those skilled in the art.

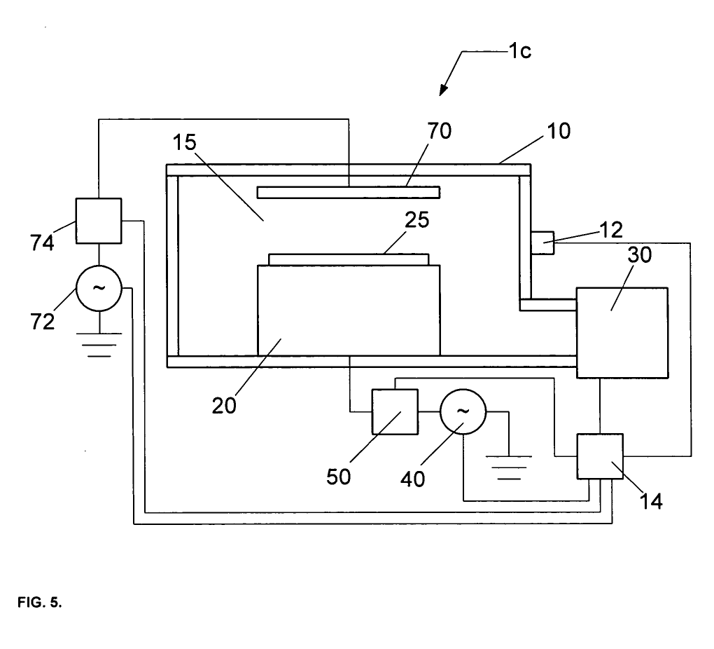

In the embodiment shown in FIG. 5, the plasma processing system 1c can be similar to the embodiment of FIG. 2 or FIG. 3, and can further comprise an upper electrode 70 to which RF power can be coupled from RF generator 72 through impedance match network 74. A frequency for the application of RF power to the upper electrode can range from about 0.1 MHz to about 200 MHz. Additionally, a frequency for the application of power to the lower electrode can range from about 0.1 MHz to about 100 MHz. Moreover, controller 14 is coupled to RF generator 72 and impedance match network 74 in order to control the application of RF power to upper electrode 70. The design and implementation of an upper electrode is well known to those skilled in the art.

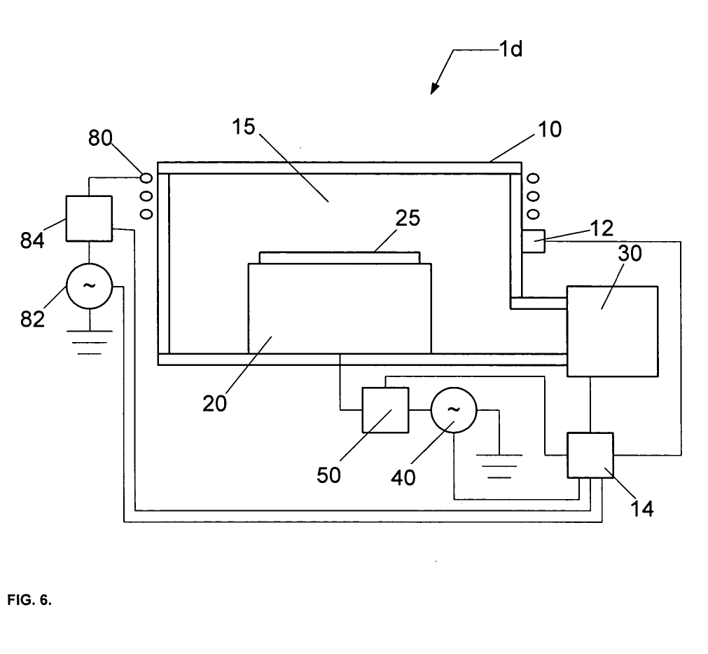

In the embodiment shown in FIG. 6, the plasma processing system 1d can be similar to the embodiments of FIGS. 2 and 3, and can further comprise an inductive coil 80 to which RF power is coupled via RF generator 82 through impedance match network 84. RF power is inductively coupled from inductive coil 80 through a dielectric window (not shown) to plasma processing region 45. A typical frequency for the application of RF power to the inductive coil 80 can range from about 10 MHz to about 100 MHz. Similarly, a typical frequency for the application of power to the chuck electrode can range from about 0.1 MHz to about 100 MHz. In addition, a slotted Faraday shield (not shown) can be employed to reduce capacitive coupling between the inductive coil 80 and plasma. Moreover, controller 14 is coupled to RF generator 82 and impedance match network 84 in order to control the application of power to inductive coil 80. In an alternate embodiment, inductive coil 80 can be a “spiral” coil or “pancake” coil in communication with the plasma processing region 15 from above as in a transformer coupled plasma (TCP) reactor. The design and implementation of an inductively coupled plasma (ICP) source, or transformer coupled plasma (TCP) source, is well known to those skilled in the art.

Alternately, the plasma can be formed using electron cyclotron resonance (ECR). In yet another embodiment, the plasma is formed from the launching of a Helicon wave. In yet another embodiment, the plasma is formed from a propagating surface wave. Each plasma source described above is well known to those skilled in the art.

In the following discussion, a method of etching an organic layer, such as an organic ARC layer, an organic mask layer, a combination thereof, or the like, utilizing a plasma processing device is presented. The plasma processing device can comprise various elements, such as described in FIGS. 2 through 6, and combinations thereof.

In one embodiment, the method of etching an organic layer comprises an NₓO_{y} based chemistry. For example, a process parameter space can comprise a chamber pressure of about 20 to about 1000 mTorr, an NO process gas flow rate ranging from about 50 to about 1000 sccm, an upper electrode (e.g., element 70 in FIG. 5) RF bias ranging from about 500 to about 2000 W, and a lower electrode (e.g., element 20 in FIG. 5) RF bias ranging from about 10 to about 500 W. Also, the upper electrode bias frequency can range from about 0.1 MHz to about 200 MHz, e.g., about 60 MHz. In addition, the lower electrode bias frequency can range from about 0.1 MHz to about 100 MHz, e.g., about 2 MHz.

In an alternate embodiment, the method of etching an organic layer can comprise an NO₂ based chemistry. The process parameter space can comprise a chamber pressure of about 20 to about 1000 mTorr, an NO₂ process gas flow rate ranging from about 50 to about 1000 sccm, an upper electrode (e.g., element 70 in FIG. 5) RF bias ranging from about 500 to about 2000 W, and a lower electrode (e.g., element 20 in FIG. 5) RF bias ranging from about 10 to about 500 W.

In an alternate embodiment, the method of etching an organic layer can comprise an N₂O based chemistry. The process parameter space can comprise a chamber pressure of about 20 to about 1000 mTorr, an N₂O process gas flow rate ranging from about 50 to about 1000 sccm, an upper electrode (e.g., element 70 in FIG. 5) RF bias ranging from about 500 to about 2000 W, and a lower electrode (e.g., element 20 in FIG. 5) RF bias ranging from about 10 to about 500 W.

In an alternate embodiment, any mixture thereof can be utilized.

In general, the etch time can be determined using design of experiment (DOE) techniques; however, it can also be determined using endpoint detection. One possible method of endpoint detection is to monitor a portion of the emitted light spectrum from the plasma region that indicates when a change in plasma chemistry occurs due to substantially near completion of the organic layer etching and contact with the underlying material film. For example, portions of the spectrum that indicate such changes comprise wavelengths of 387.2 nm (CN), and can be measured using optical emission spectroscopy (OES). After emission levels corresponding to those frequencies cross a specified threshold (e.g., drop to substantially zero or increase above a particular level), an endpoint can be considered to be complete. Other wavelengths that provide endpoint information can also be used. Furthermore, the etch time can be extended to include a period of over-etch, wherein the over-etch period constitutes a fraction (i.e. 1 to 100%) of the time between initiation of the etch process and the time associated with endpoint detection.

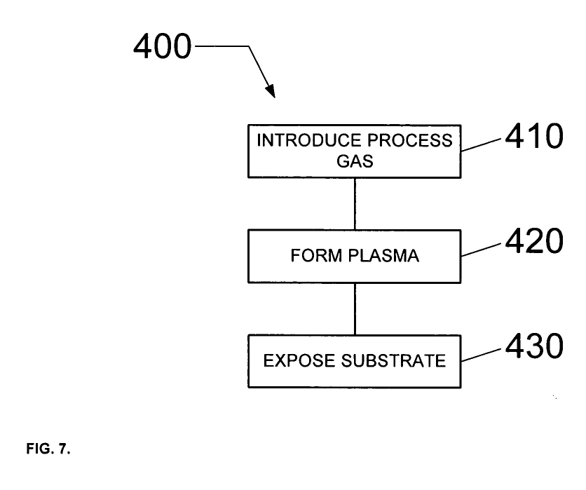

FIG. 7 presents a flow chart of a method for etching an organic layer, such as an organic anti-reflective coating (ARC) layer, an organic mask layer, a combination thereof or the like, on a substrate in a plasma processing system according to an embodiment of the present invention. Procedure 400 begins in 410 in which a process gas is introduced to the plasma processing system, wherein the process gas comprises NₓO_{y}, wherein x and y are integers greater than or equal to unity. For example, the process gas can comprise NO, NO₂, or N₂O. Alternately, the process gas can further comprise an inert gas, such as a Noble gas (i.e., He, Ne, Ar, Kr, Xe, Rn).

In 420, a plasma is formed in the plasma processing system from the process gas using, for example, any one of the systems described in FIGS. 2 through 6, and combinations thereof.

In 430, the substrate comprising the organic layer is exposed to the plasma formed in 420. After a first period of time, procedure 400 ends. The first period of time during which the substrate with the organic layer is exposed to the plasma can generally be dictated by the time required to etch the organic layer, or the time required to transfer a photoresist pattern to the organic layer. In general, the first period of time required to transfer a photoresist pattern through the thickness of the organic layer is pre-determined. Alternately, the first period of time can be further augmented by a second period of time, or an over-etch time period. As described above, the over-etch time can comprise a fraction of time, such as 1 to 100%, of the first period of time, and this over-etch period can comprise an extension of etching beyond the detection of endpoint.

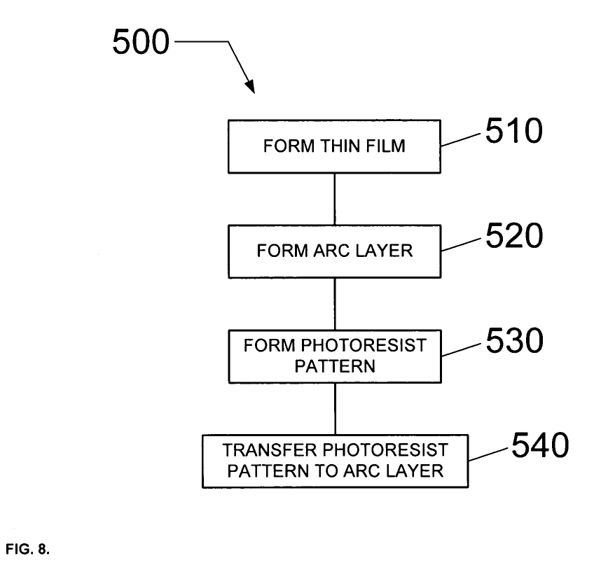

FIG. 8 presents a method for forming a bilayer mask for etching a thin film on a substrate in a plasma processing system according to another embodiment of the present invention. The method is illustrated in a flowchart 500 beginning in 510 with forming the thin film on the substrate. The thin film can comprise an oxide layer, such as silicon dioxide (SiO₂), and it can be formed by a variety of processes including chemical vapor deposition (CVD).

In 520, an organic layer, such as an organic anti-reflective coating (ARC) layer, an organic mask layer, a combination thereof or the like, is formed on the substrate overlying the thin film. The organic layer can be formed using conventional techniques such as a spin coating system.

In 530, a photoresist pattern is formed on the substrate overlying the organic layer. The photoresist film can be formed using conventional techniques, such as a photoresist spin coating system. The pattern can be formed within the photoresist film by using conventional techniques such as a stepping micro-lithography system, and a developing solvent.

In 540, the photoresist pattern is transferred to the organic layer in order to form the bilayer mask. The pattern transfer is accomplished using a dry etching technique, wherein the etch process is performed in a plasma processing system that utilizes a process gas comprising NₓO_{y}, wherein x and y are integers greater than or equal to unity. For example, the process gas can comprise NO, NO₂, or N₂O. Alternately, the process gas can further comprise an inert gas, such as a Noble gas (i.e., He, Ne, Ar, Kr, Xe, Rn). Plasma is formed in the plasma processing system from the process gas using, for example, any one of the systems described in FIGS. 2 through 6, and the substrate comprising the organic layer is exposed to the plasma formed. A first period of time during which the substrate with the organic layer is exposed to the plasma can generally be dictated by the time required to etch the organic layer, or the time required to transfer a photoresist pattern to the organic layer. In general, the first period of time required to transfer a photoresist pattern through the thickness of the organic layer is pre-determined. However, the first period of time can be further augmented by a second period of time, or an over-etch time period. As described above, the over-etch time can comprise a fraction of time, such as 1 to 100%, of the first period of time, and this over-etch period can comprise an extension of etching beyond the detection of endpoint.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method for etching an organic anti-reflective coating (ARC) layer on a substrate in a plasma processing system comprising:
introducing a process gas comprising NₓO_{y}, wherein x and y are integers greater than or equal to unity;
forming a plasma from said process gas in said plasma processing system; and
exposing said organic ARC layer on said substrate to said plasma.

2. The method as recited in claim 1, wherein said introducing of said process gas comprises introducing at least one of NO, NO₂, and N₂O.

3. The method as recited in claim 1, wherein said introducing of said process gas further comprises introducing an inert gas.

4. The method as recited in claim 3, wherein said introducing of said inert gas comprises introducing a Noble gas.

5. The method as recited in claim 1, wherein said exposing comprises exposing said organic ARC layer for a first period of time.

6. The method as recited in claim 5, wherein said exposing for said first period of time comprises determining said first period of time by endpoint detection.

7. The method as recited in claim 6, wherein said determining of said first period of time by endpoint detection comprises utilizing optical emission spectroscopy.

8. The method as recited in claim 5, wherein said exposing for said first period of time is followed by exposing said substrate or said organic ARC layer to said plasma for a second period of time.

9. The method as recited in claim 8, wherein said exposing for said second period of time comprises exposing said substrate to said plasma for a fraction of said first period of time.

10. A method of forming a bilayer mask for etching a thin film on a substrate comprising:
forming said thin film on said substrate;
forming an organic anti-reflective coating (ARC) layer on said thin film;
forming a photoresist pattern on said organic ARC layer; and
transferring said photoresist pattern to said organic ARC layer by plasma etching said ARC layer using a process gas comprising NₓO_{y}, wherein x and y are integers greater than or equal to unity.

11. The method as recited in claim 10, wherein said using of said process gas comprises using at least one of NO, NO₂, and N₂O.

12. The method as recited in claim 10, wherein said using of said process gas further comprises using an inert gas.

13. The method as recited in claim 12, wherein said using of said inert gas comprises using a Noble gas.

14. The method as recited in claim 10, wherein said transferring is performed for a first period of time.

15. The method as recited in claim 14, wherein said transferring for said first period of time is determined by endpoint detection.

16. The method as recited in claim 15, wherein said determining of said first period of time by endpoint detection comprises utilizing optical emission spectroscopy.

17. The method as recited in claim 14, wherein said transferring for said first period of time is followed by plasma etching said substrate or said ARC layer for a second period of time.

18. The method as recited in claim 17, wherein said plasma etching for said second period of time comprises exposing said substrate to said plasma for a fraction of said first period of time.

19. A plasma processing system for etching an organic anti-reflective coating (ARC) layer on a substrate comprising:
a plasma processing chamber for facilitating the formation of a plasma from a process gas; and
a controller coupled to said plasma processing chamber and configured to execute a process recipe utilizing said process gas to etch said organic ARC layer, wherein said process gas comprises NₓO_{y}, and x and y are integers greater than or equal to unity.

20. The system as recited in claim 19, further comprising a diagnostic system coupled to said plasma processing chamber, and coupled to said controller.

21. The system as recited in claim 20, wherein said diagnostic system is configured to receive a signal that is related to light emitted from said plasma.

22. The system as recited in claim 19, wherein said process gas comprises at least one of NO, NO₂, and N₂O.

23. The system as recited in claim 19, wherein said process gas further comprises an inert gas.

24. The system as recited in claim 23, wherein said inert gas comprises a Noble gas.

25. The system as recited in claim 20, wherein said controller causes said organic ARC layer to be exposed to said plasma for a first period of time.

26. The system as recited in claim 25, wherein said first period of time is determined by endpoint detection determined by said diagnostic system.

27. The system as recited in claim 26, wherein said diagnostic system comprises an optical emission spectroscopy device.

28. The system as recited in claim 25, wherein said first period of time corresponds to the time to etch said organic ARC layer and is extended by a second period of time.

29. The system as recited in claim 28, wherein said second period of time is a fraction of said first period of time.

30. A method for etching an organic layer on a substrate in a plasma processing system comprising:
introducing a process gas comprising NₓO_{y}, wherein x and y are integers greater than or equal to unity;
forming a plasma from said process gas in said plasma processing system; and
exposing said organic layer on said substrate to said plasma.

31. The method as recited in claim 30, wherein said introducing of said process gas comprises introducing at least one of NO, NO₂, and N₂O.

32. The method as recited in claim 30, wherein said introducing of said process gas further comprises introducing an inert gas.

33. The method as recited in claim 32, wherein said introducing of said inert gas comprises introducing a Noble gas.

34. The method as recited in claim 30, wherein said exposing comprises exposing said organic layer for a first period of time.

35. The method as recited in claim 34, wherein said exposing for said first period of time comprises determining said first period of time by endpoint detection.

36. The method as recited in claim 35, wherein said determining of said first period of time by endpoint detection comprises utilizing optical emission spectroscopy.

37. The method as recited in claim 34, wherein said exposing for said first period of time is followed by exposing said substrate or said organic layer to said plasma for a second period of time.

38. The method as recited in claim 37, wherein said exposing for said second period of time comprises exposing said substrate to said plasma for a fraction of said first period of time.

39. The method as recited in claim 30, wherein said exposing said organic layer includes exposing at least one of an organic anti-reflective coating (ARC) layer and an organic mask layer.

40. A method of forming a bilayer mask for etching a thin film on a substrate comprising:
forming said thin film on said substrate;
forming an organic layer on said thin film;
forming a photoresist pattern on said organic layer; and
transferring said photoresist pattern to said organic layer by plasma etching said organic layer using a process gas comprising NₓO_{y}, wherein x and y are integers greater than or equal to unity.

41. The method as recited in claim 40, wherein said using of said process gas comprises using at least one of NO, NO₂, and N₂O.

42. The method as recited in claim 40, wherein said using of said process gas further comprises using an inert gas.

43. The method as recited in claim 42, wherein said using of said inert gas comprises using a Noble gas.

44. The method as recited in claim 40, wherein said transferring is performed for a first period of time.

45. The method as recited in claim 44, wherein said transferring for said first period of time is determined by endpoint detection.

46. The method as recited in claim 45, wherein said determining of said first period of time by endpoint detection comprises utilizing optical emission spectroscopy.

47. The method as recited in claim 44, wherein said transferring for said first period of time is followed by plasma etching said substrate or said organic layer for a second period of time.

48. The method as recited in claim 47, wherein said plasma etching for said second period of time comprises exposing said substrate to said plasma for a fraction of said first period of time.

49. The method as recited in claim 40, wherein said forming said organic layer includes forming at least one of an organic anti-reflective coating (ARC) layer and an organic mask layer.

50. A plasma processing system for etching an organic layer on a substrate comprising:
a plasma processing chamber for facilitating the formation of a plasma from a process gas; and
a controller coupled to said plasma processing chamber and configured to execute a process recipe utilizing said process gas to etch said organic layer, wherein said process gas comprises NₓO_{y}, and x and y are integers greater than or equal to unity.

51. The system as recited in claim 50, further comprising a diagnostic system coupled to said plasma processing chamber, and coupled to said controller.

52. The system as recited in claim 51, wherein said diagnostic system is configured to receive a signal that is related to light emitted from said plasma.

53. The system as recited in claim 50, wherein said process gas comprises at least one of NO, NO₂, and N₂O.

54. The system as recited in claim 50, wherein said process gas further comprises an inert gas.

55. The system as recited in claim 54, wherein said inert gas comprises a Noble gas.

56. The system as recited in claim 51, wherein said controller causes said organic layer to be exposed to said plasma for a first period of time.

57. The system as recited in claim 56, wherein said first period of time is determined by endpoint detection determined by said diagnostic system.

58. The system as recited in claim 57, wherein said diagnostic system comprises an optical emission spectroscopy device.

59. The system as recited in claim 56, wherein said first period of time corresponds to the time to etch said organic layer and is extended by a second period of time.

60. The system as recited in claim 59, wherein said second period of time is a fraction of said first period of time.

61. The system as recited in claim 50, wherein said organic layer comprises at least one of an organic anti-reflective coating (ARC) layer and an organic mask layer.
